(19) United States
(12) Patent Application Publication
(10) Pub. No.: US 2015/0348787 A1
(43) Pub. Date: Dec. 3, 2015

(54) SEMICONDUCTOR DEVICES AND METHODS FOR FORMING A GATE WITH REDUCED DEFECTS

(71) Applicant: GLOBALFOUNDRIES INC., Grand Cayman (KY)

(72) Inventor: Xiuyu CAI, Niskayuna, NY (US)

(73) Assignee: GLOBALFOUNDRIES INC., Grand Cayman (KY)

(21) Appl. No.: 14/288,551

(22) Filed: May 28, 2014

(51) Int. Cl. H01L 21/28; H01L 21/3213; H01L 21/321; H01L 29/49; H01L 29/66; H01L 21/027

(52) U.S. Cl. CPC H01L 21/28035; H01L 29/66545; H01L 29/66568; H01L 21/0276; H01L 21/321; H01L 29/4916; H01L 21/32139

(57) ABSTRACT

A method for forming a gate of a semiconductor device includes providing a semiconductor substrate, forming an active region with trench isolation in the semiconductor substrate, providing a polysilicon layer disposed on the semiconductor substrate, and providing a hard mask layer disposed on the polysilicon layer. An ash resistant layer is disposed on the hard mask layer. Patterned portions of the ash resistant layer, the hard mask, and the polysilicon layer are moved, and the remaining portions of the ash resistant layer is wherein the patterned polysilicon layer defines the gate. The resistant layer inhibits or reduces the likelihood of pitting of the polysilicon layer and substrate during subsequent etching processes.

### TECHNICAL FIELD

The present invention relates generally to conductive circuits and methods of forming conductive circuits, and more particularly, to semiconductor structures and methods for forming a gate with reduced defects.

### BACKGROUND OF THE DISCLOSURES

Various processing steps are used to fabricate integrated circuits on a semiconductor substrate. The steps typically include sequential deposition of conductive and insulative layers on the silicon substrate. A conventional process for patterning a polysilicon gate employs a hard mask. Such a process includes depositing a gate oxide layer on a substrate, depositing a polysilicon layer on the gate oxide layer, depositing a hard mask layer on the polysilicon layer, depositing a lithographic stack having an organic planarizing layer, an anti-reflective coating layer, and a patterned photo resist layer. Portions of the anti-reflective coating layer, the organic planarizing layer, and the hard mask layer are removed according to the patterned photoresist layer, and then removal of the remaining portions of the photoresist layer, anti-reflective coating layer, organic planarizing layer are removed from the patterned hard mask layer.

If any pin holes exist in the anti-reflective coating layer, the removal of the photoresist layer such as using plasma ashing can punch through the lithographic stack. If there is damage at the hard mask, subsequent hard mask removal such as etching can leave more gouging on the polysilicon layer. The subsequent polysilicon removal or etch will pouch through gate oxide and etch the silicon substrate causing the formation of Si pitting.

There is a need for conductive circuits and methods for forming conductive circuits, and more particularly, to semiconductor structures and methods for forming a gate with reduced defects.

### SUMMARY OF THE DISCLOSURE

There is provided, in a first aspect, a method for forming a gate of a semiconductor device. The method includes providing a semiconductor substrate, forming an active region with trench isolation in the semiconductor substrate, providing a polysilicon layer disposed on the semiconductor substrate, providing a hard mask layer disposed on the polysilicon layer, providing an ash resistant layer disposed on the hard mask layer, removing patterned portions of the ash resistant layer, the hard mask, and the polysilicon layer, and removing the remaining portions of the ash resistant layer wherein the patterned polysilicon layer defines the gate.

There is provided, in a second aspect, a semiconductor structure for use in forming a gate. The semiconductor structure includes a semiconductor substrate having an active region with trench isolation in said semiconductor substrate, a polysilicon layer disposed on said semiconductor substrate, a hard mask disposed on said polysilicon layer, and an ash resistant layer disposed on said hard mask layer. In addition, a lithographic stack may be disposed on said hard mask, or portions of the ash resistant layer, the hard mask, and the polysilicon layer may be removed to define a gate pattern on the semiconductor substrate.

Additional features and advantages are realized through the techniques of the present disclosure. Other embodiments and aspects of the present disclosure are described in detail herein and are considered a part of the claimed invention.

### BRIEF DESCRIPTION OF THE DRAWINGS

The subject matter which is regarded as the invention is particularly pointed out and distinctly claimed in the concluding portion of the specification. The invention, however, may best be understood by reference to the following detailed description of various embodiments and the accompanying drawings in which:

FIG. 1 is a cross-sectional view of an intermediate circuit structure for fabricating a gate of a semiconductor device in accordance with the present disclosure;

FIG. 2 is a cross-sectional view of the intermediate circuit structure of FIG. 1 with an ash resistant layer disposed thereon;

FIG. 3 is a cross-sectional view of the intermediate circuit structure and ash resistant layer of FIG. 2 with a lithographic stack disposed on the ash resistant layer;

FIG. 4 is a cross-sectional view of the structure of FIG. 3 with removal of portions of the lithographic stack, the ash resistant layer, and the intermediate circuit structure in accordance with the patterned photoresist layer;

FIG. 5 is a side view of the structure of FIG. 4;

FIG. 6 is a cross-sectional view of the patterned intermediate circuit structure of FIG. 4 with the remaining patterned ash resistant layer removed;

FIG. 7 is a side view of the structure of FIG. 6; and

FIG. 8 is a flowchart of one illustrative embodiment of a method for forming a gate in accordance with one or more aspects of the present disclosure.

### DETAILED DESCRIPTION OF THE DISCLOSURE

Aspects of the present disclosure and certain features, advantages, and details thereof, are explained more fully below with reference to the non-limiting embodiments illustrated in the accompanying drawings. Descriptions of well-known materials, fabrication tools, processing techniques, etc., are omitted so as to not unnecessarily obscure the disclosure in detail. It should be understood, however, that the detailed description and the specific examples, while indicating embodiments of the invention, are given by way of illustration only, and are not by way of limitation. Various substitutions, modifications, additions and/or arrangements within the spirit and/or scope of the underlying inventive concepts will be apparent to those skilled in the art from this disclosure. Reference is made below to the drawings, which are not drawn to scale for ease of understanding, wherein the same reference numbers used throughout different figures designate the same or similar components.

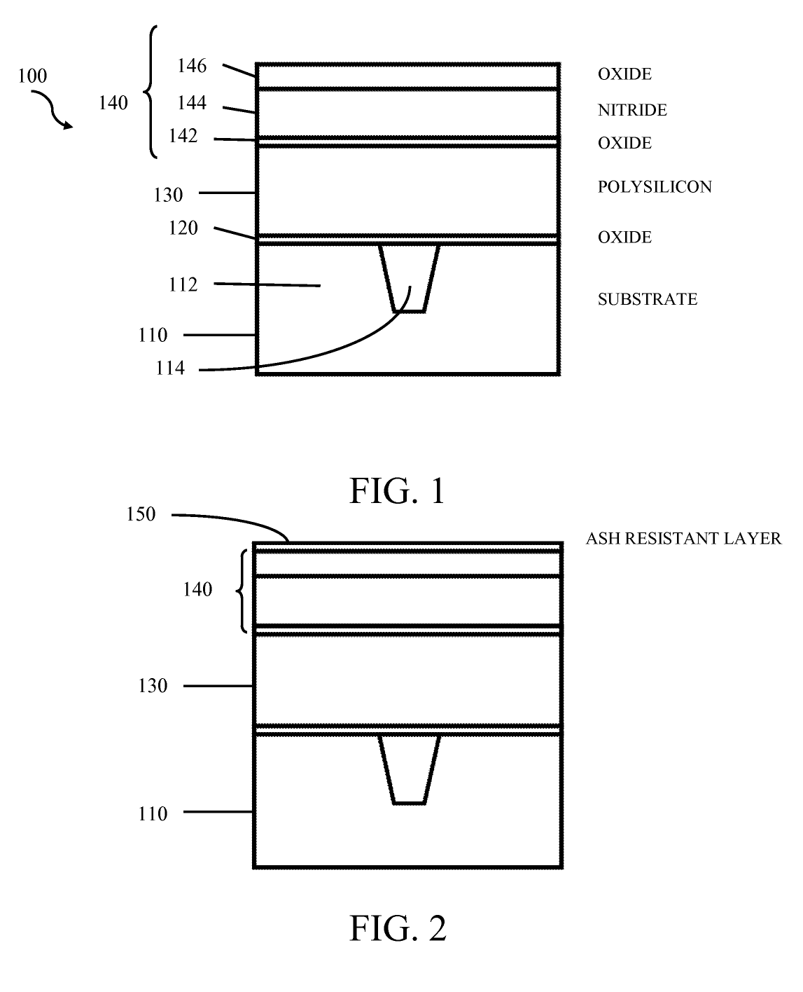

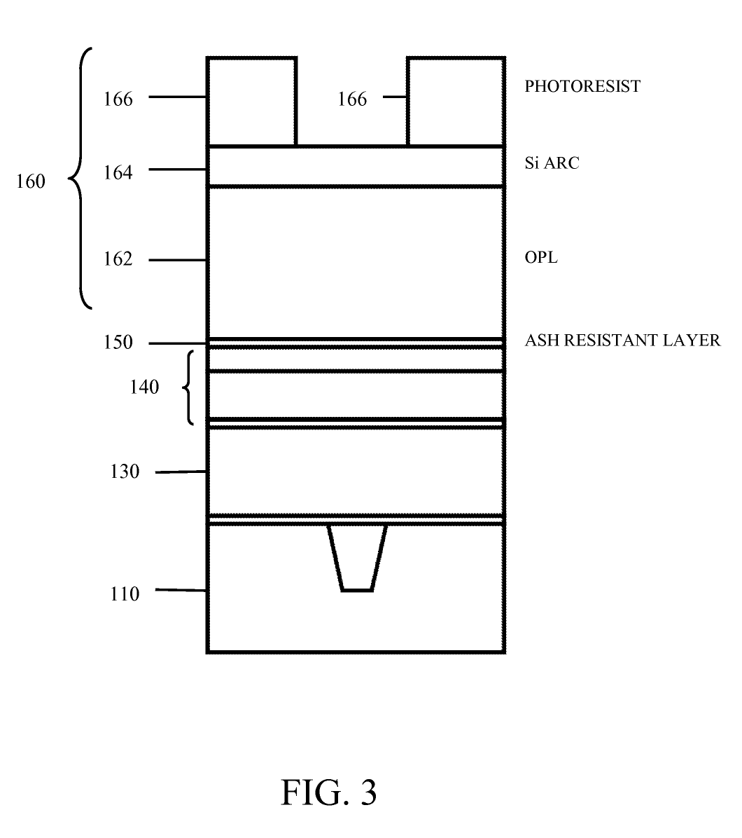

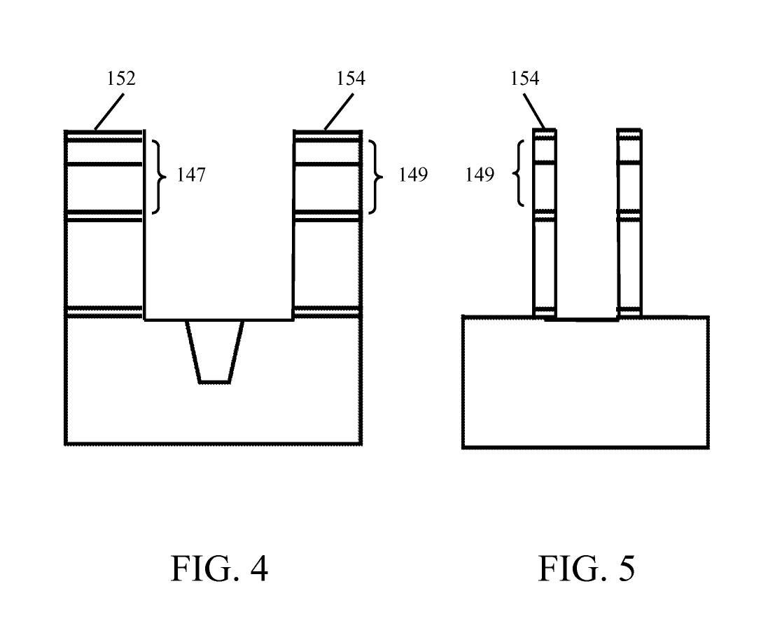

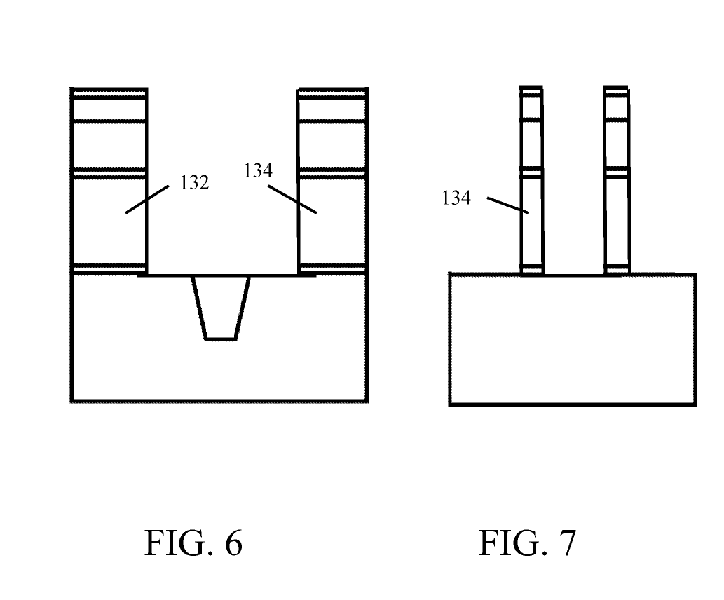

FIG. 1 schematically illustrates an intermediate circuit structure 100, which can be obtained during fabrication of a conductive circuit, such as a gate. For example, intermediate circuit structure 100 may include a substrate 110, a polysilicon film 130, and a hard mask 140. As shown in FIG. 2, and described further below, an ash resistant layer 150 is deposited on hard mask 140, prior to depositing a lithographic stack 160 on the ash resistant layer as shown in FIG. 3. The ash resistant layer inhibits the likelihood of formation of pitting in the polysilicon film and substrate when lithographic stack and portions of the hard mask are later removed as described below and as shown in FIGS. 4 and 5. Thereafter, the ash resistant layer is removed as shown in FIGS. 6 and 7.

With reference again to FIG. 1, substrate 110 may include, for example, a semiconductor material. As one skilled in the art will understand, where, as in the present example, a semiconductor material is used, many gates may be formed, such that what is shown in FIG. 1 is repeated a large number of times across the substrate such as a wafer. The semiconductor material may include, but not limited to, silicon (Si), germanium (Ge), a compound semiconductor material, a layered semiconductor material, a silicon-on-insulator (SOI) material, a SiGe-on-insulator (SGOI) material, and/or a germanium-on-insulator (GOI) material.

While the present discussion is directed to formation of gates disposed over substrate 110 employing a “gate-first process”, one skilled in art will appreciate that the gates may be fabricated using a “gate-last process” (also referred to as replacement metal gate process).

Substrate 110 may in addition or instead include various isolations, dopings and/or device features. For example, an active region 112, and an isolation region 114 may be defined on a semiconductor substrate 110 using an isolation process. The formation of isolation regions, such as isolation trenches, may typically include forming a recess on the substrate and filling the recess with a dielectric film using a chemical vapor deposition (CVD) process, for example, a low pressure CVD (LPCVD), a high-density CVD (HDCVD), or plasma enhanced CVD (PECVD), then performing a chemical mechanical polish (CMP) to remove any excess dielectric film filling the shallow isolation trenches. The isolation regions 114 may be filled with dielectric materials, for example, silicon oxide, silicon nitride, and the like. The isolation regions may then be annealed.

A dielectric layer 120, for example, a gate oxide, may be disposed on substrate 110. In one example, a dielectric layer may include silicon dioxide (SiO₂) and may be thermally grown or deposited by a number of different processes, for example, a chemical vapor deposition (CVD) process.

For forming a gate, as described further below, polycrystalline silicon layer or polysilicon layer 130 is deposited on the dielectric layer. For example, polysilicon layer may be a homoepitaxial layer of polycrystalline silicon deposited using conventional processes, for example, chemical vapor deposition. It will be appreciated that other materials may be employed for forming the gate.

Hard mask 140 may include one or more layers. For example, hard mask 140 may include a first hard mask layer 142, a second hard mask layer 144, and third hard mask layer 146. In one embodiment, first hard mask layer 142 may be an oxide layer, second hard mask layer 144 may be a nitride layer deposited on oxide layer 142, third hard mask layer 146 may be an oxide layer deposited on nitride layer 144. For example, the oxide layer may be silicon dioxide layer. In other embodiments, the oxide layer may include any suitable dielectric oxide material or dielectric materials, including silicon dioxide, fluorine doped silicon glass FSG), tetraethylorthosilicate (TEOS), phosphosilicate glass (PSG), borophosphosilicate glass (BPSG), any suitable spin-on glass, or low k polymer materials. The nitride layer may be a silicon nitride layer formed using any suitable technique, including but not limited to CVD techniques.

With reference to FIG. 2, in accordance with aspects of the present disclosure, ash resistant layer 150 is deposited on the hard mask 140. Ash resistant layer 140 inhibits or reduces the likelihood of pitting of polysilicon layer 130 and substrate 110. In one example, the ash resistant layer may be a hafnium (IV) oxide (HfO2) layer deposited on the hard mask. As will be appreciated form the description below, HfO2 is highly resistant to plasma wet etching which involves CF4 and oxidation chemistry. For example, to prevent or inhibit pitting, the ash resistant layer may be about 2 nanometers thick. In one embodiment, a continuous 2 nanometer HfO2 layer may be suitably employed. Hafnium (IV) oxide is an inorganic compound, and is known as hafnia, a colourless solid, a common and stable compounds of hafnium.

FIG. 3 illustrates lithographic stack 160 disposed over ash resistant layer 150. In one embodiment, lithographic stack 160 may include an organic planarizing layer (OPL) 162, an anti-reflective coating material layer 164 and a patterned photoresist layer 166. As will be subsequently explained, semiconductor fabrication processing of the intermediate semiconductor structure generally proceeds by patterning of the structure to create openings over the various active regions. The organic planarizing layer may be used to transfer a pattern from the overlying photoresist layer in subsequent lithography processing, and may be formed using conventional spin-coating processes. In one example, an organic planarizing layer may be any of those conventionally employed during a pattern transfer process and may include an organic polymer, for example, polyacrylate resin, epoxy resin, phenol resin, polyamide resin, polyimide resin, unsaturated polyester resin, polyphenylenether resin, polyphenylenesulfide resin, or benzocyclobutene (BCB). The thickness of the organic planarizing layer may preferably be about 50 nanometers to about 200 nanometers.

An anti-reflective coating material layer, may be, for example, a silicon anti-reflective layer (Si-ARC), deposited over the organic planarizing layer (OPL) to minimize any pattern distortion due to reflections. The anti-reflective coating material layer may include materials having silicon and nitrogen, silicon and oxygen, or silicon, oxygen and nitrogen, or an organic polymer, or combinations thereof. The thickness of the anti-reflecting coating material layer may preferably be about 20 nanometers to about 40 nanometers. As is known, a layer of light sensitive material, such as, for example, the photo resist layer, protecting the underlying layers in the direction of etching during the subsequent etch processing, is deposited over the anti-reflective coating material layer. The thickness of the photo resist layer may preferably be in the range of about 60 nanometers to about 100 nanometers. The layer of photo resist also defines the openings through which the etch process proceeds and may include a conventional positive photo resist material, such as, for example, organic photo resist materials, non-organic materials or combinations thereof.

With reference still to FIG. 3, portions of anti-reflective coating layer 164, organic planarizing layer 162, ash resistant layer 150, and hard mask layer 140 may be removed according to the patterned photoresist layer, and then removal of the photoresist layer and the remaining anti-reflective coating layer, and the organic planarizing layer resulting in the structure shown in FIGS. 4 and 5. For example, an etching process or processes may be employed to remove portions of the anti-reflective coating material layer 164 (FIG. 3), organic planarizing layer 162 (FIG. 3), portions of the ash resistant layer 150 (FIG. 3), and portions of the hard mask layer 140 (FIG. 3) as is well known in the art. Removal process or processes such as stripping of the photo resist layer 166 (FIG. 3), the underlying anti-reflective coating material layer 164 (FIG. 3), and organic planarizing layer 162 may be performed as is well known in the art.

As will be appreciated, the ash resistant layer inhibits pitting of underlying structure during the removal of the patterned structure, and subsequent removal of the patterned lithographic stack. Thereafter, the remaining portions 152 (FIG. 4) and 154 (FIG. 5) of the ash resist layer, disposed on the remaining portions 147 and 149 of the hard mask layer, may be removed by BCl3 chemistry, resulting in the structure having a gate 132 and a gate 134 as shown in FIGS. 6 and 7.

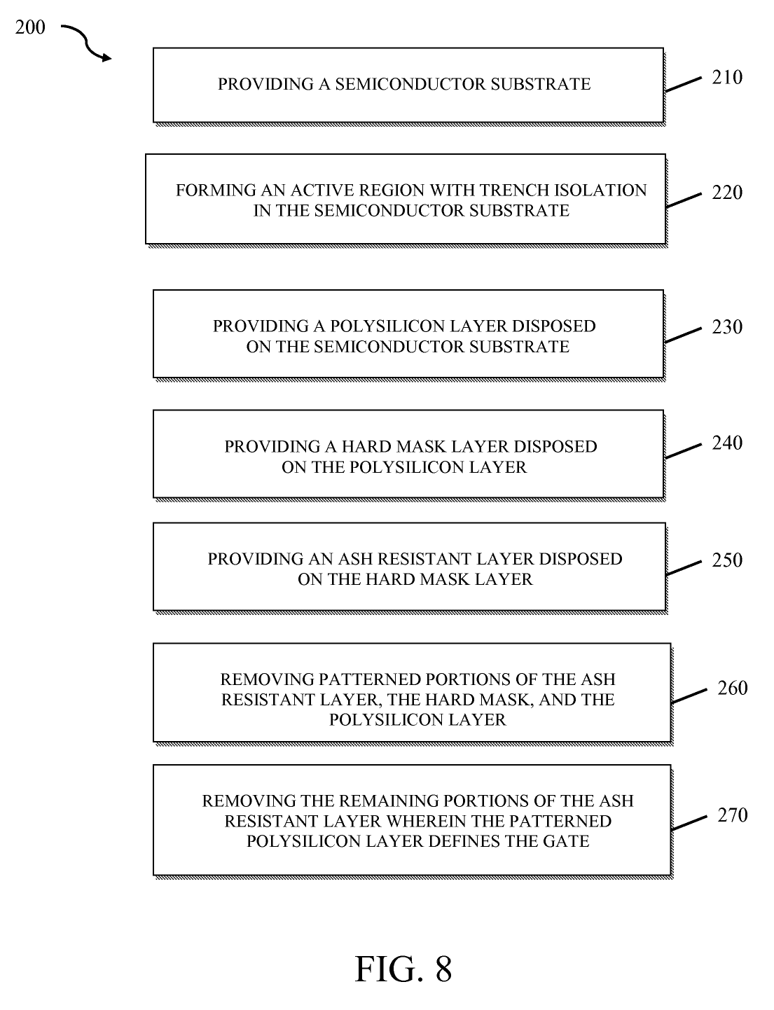

The description presented herein above can be further illustrated by FIG. 8 depicting a flowchart of one illustrative embodiment of a method 200 of fabricating a gate or a contact structure of a conductive circuit. In the illustrative embodiment, method 200 may include, at 210, providing a semiconductor substrate, at 220, forming an active region with trench isolation in the semiconductor substrate, at 230, providing a polysilicon layer disposed on the semiconductor substrate, and at 240, providing hard mask layer disposed on the polysilicon layer. At 250, an ash resistant layer is provided on the hard mask layer. Patterned portions of the ash resistant layer, the hard mask, and the polysilicon layer are removed at 260, and at 270, remaining portions of the ash resistant layer are removed wherein the patterned polysilicon layer defines the gate.

As described above, the HfO2 removal may occur after gate stack patterning. For example, HfO2 could be removed at this point using BCl3 chemistry, which is highly selective to SiO2/SiN/Si. HfO2 may be removed after forming the gate, which may be advantage to maintain uniform gate height. The oxide on the top of the nitride serves the purpose of keeping a uniform gate height through gate formation. If HfO2 is used, the oxide thickness can be reduced as well as gate aspect ratio accordingly which will expand the process window for poly gate etch and gate spacer etch.

In another embodiment, the HfO2 layer may be removed during oxide/nitride hard mask open with an additional steps of HfO2 removal.

Substrate pitting is a yield loss contributor in the fabrication of semiconductor devices due to the need for gate lithographic reworks. Data mining indicated that there is about a 2 percent yield loss per rework time. The technique of the present disclosure may reduce such loss in the fabrication of gates.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

1. A method for forming a gate of a semiconductor device, the method comprising:
providing a semiconductor substrate;
forming an active region with trench isolation in the semiconductor substrate;
providing a polysilicon layer disposed on the semiconductor substrate;
providing a hard mask layer disposed on the polysilicon layer;
providing an ash resistant layer disposed on the hard mask layer;
forming a patterned gate on the semiconductor substrate by removing patterned portions of the ash resistant layer, the hard mask, and the polysilicon layer;
removing the remaining portions of the ash resistant layer from the remaining hard mask.

2. The method of claim 1 wherein the patterned polysilicon layer defines a final gate or the patterned polysilicon layer defines a dummy gate for use in a replacement gate process.

3. The method of claim 1 wherein the removing the remaining portions of the ash resistant layer occurs during the forming of the gate.

4. The method of claim 1 wherein the removing the remaining portions of the ash resistant layer from the gate pattern occurs after the forming of the gate.

5. The method of claim 1 wherein the forming a patterned gate comprises providing a lithographic stack disposed on the hard mask.

6. The method of claim 5 wherein the lithographic stack comprises an organic planarizing layer, an anti-reflective coating material layer, and a photoresist layer.

7. The method of claim 1 wherein the ash resistant layer is resistant to fluorine and oxidation chemistry.

8. The method of claim 1 wherein the ash resistant layer comprises HfO2.

9. The method of claim 8 wherein the resistant layer comprises a thickness of about 2 nanometers.

10. The method of claim 8 wherein the removing the ash resistant layer from the gate pattern comprises using BCl3 chemistry.

11. The method of claim 1 wherein the hard mask comprises an oxide layer, a nitride layer, and an oxide layer.

12. The method of claim 1 wherein the forming the gate pattern comprises at least one of a reactive ion etching process and a wet etching process.

13-19. (canceled)

20. The method of claim 1 wherein said hard mask comprises a nitride layer and an oxide layer.
